(19) United States
(12) Patent Application Publication
(10) Pub. No.: US 2008/0251799 A1
(43) Pub. Date: Oct. 16, 2008

(54) LIGHT EMITTING DEVICE

(75) Inventor: Kazuhiro Ikezawa, Fukuoka-ken (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 12/099,851

(22) Filed: Apr. 9, 2008

(30) Foreign Application Priority Data
Apr. 13, 2007 (JP) 2007-105976

(51) Int. Cl. H01L 33/00

(52) U.S. Cl. 257/89; 257/E33.001

(57) ABSTRACT

A visible light emitting device includes: three types of LED elements stacked one on another; and first and second optical filters. Each of the LED elements has a light emitting layer configured to emit light of one of three primary colors. Each of the first and second optical filters is disposed between two adjacent ones of the LED elements, and each of the first and second optical filters is operable to reflect or absorb a shorter wavelength light of the lights emitted from two adjacent LED elements.

### CROSS-REFERENCE TO RELATED APPLICATIONS

This application is based upon and claims the benefit of priority from the prior Japanese Patent Application No. 2007-105976, filed on Apr. 13, 2007; the entire contents of which are incorporated herein by reference.

### BACKGROUND OF THE INVENTION

1. Field of the Invention

This invention relates to a light emitting device.

2. Background Art

There are conventionally known light emitting devices with a stacked structure of three types of LED elements each having a light emitting layer for any of the three primary colors.

JP-A 10-319877(Kokai) (1998) discloses a compact light emitting device having a plurality of wavelengths and high brightness, made by combining a semiconductor light emitting element with wavelength conversion materials such as phosphors in various configurations. In this patent document, light emitting elements having different emission wavelengths are stacked into a compact multi-wavelength light source to serve as a light source for an image display device. In this light source, a red light emitting element is stacked via a connection means on a blue light emitting element, and a green light emitting element is further stacked thereon via a connection means. When a current is supplied to such stacked light emitting elements, blue light from the blue light emitting element can be extracted upward without being shaded by the other light emitting elements. Red light from the red light emitting element passes through the green light emitting element and can be extracted upward. Green light from the green light emitting element can be extracted upward without being shaded by the other light emitting elements. Thus a compact light source having high brightness can be realized by stacking light emitting elements for different colors in this manner. In this device, no filter is disposed between the elements.

JP-A 8-213657(Kokai) (1996) discloses a light emitting device in which light emitting layers for the three primary colors of blue, green, and red are bonded and stacked together by annealing to allow multicolor light emission. This document has no description on an interlayer filter. In such a structure, light with a shorter wavelength excites a light emitting element with a longer wavelength, failing to emit light of a desired color. JP-A 11-233827(Kokai) (1999) discloses a light emitting device in which light emitting layers for the three primary colors are stacked by epitaxial growth. In this light emitting device, each light emitting layer has a light confinement layer. Hence, apparently, light can be extracted only in the horizontal direction with respect to the layered structure. Furthermore, with regard to conventional white illuminations based on LED devices, it is pointed out that phosphors suitable to red light have yet to be found, resulting in poor color rendition.

### SUMMARY OF THE INVENTION

According to an aspect of the invention, there is provided a visible light emitting device including: three types of LED elements stacked one on another, each of the LED elements having a light emitting layer configured to emit light of one of three primary colors; and first and second optical filters, each of the first and second optical filters disposed between two adjacent ones of the LED elements, and each of the first and second optical filters being operable to reflect or absorb a shorter wavelength light of the lights emitted from two adjacent LED elements.

According to an aspect of the invention, there is provided a visible light emitting device including a stacked body including: a first light emitting element which emits a light having a spectrum peak at a first wavelength range; a second light emitting element which emits a light having a spectrum peak at a second wavelength range which is shorter than the first wavelength range; and an optical filter provided between the first and second light emitting elements, at least one of absorbance and reflectance of the optical filter being higher at the second wavelength range than at the first wavelength range.

According to another aspect of the invention, there is provided a visible light emitting device comprising a stacked body including: a first light emitting element which emits a light having a spectrum peak at a first wavelength range; a third light emitting element which emits a light having a spectrum peak at a third wavelength range which is different from the first wavelength range; a second light emitting element provided between the first and third light emitting elements, the second light emitting element emitting a light having a spectrum peak at a second wavelength range which is different from the first and third wavelength ranges; a first optical filter provided between the first and second light emitting elements, at least one of absorbance and reflectance of the first optical filter being higher at the second wavelength range than at the first wavelength range; and a second optical filter provided between the second and third light emitting elements, at least one of absorbance and reflectance of the second optical filter being higher at the third wavelength range than at the second wavelength range.

### BRIEF DESCRIPTION OF THE DRAWINGS

FIGS. 1A, 1B and 1C are cross-sectional views of a red LED element, a green LED element and a blue LED element according to the embodiment.

FIG. 2 is a schematic cross-sectional view of a stacked body in which the blue LED element, the green LED element, and the red LED element are stacked.

FIGS. 3A and 3B are a schematic cross-sectional view and a schematic plan view of a visible light emitting device comprising the stacked body of FIG. 2.

### DETAILED DESCRIPTION OF THE INVENTION

The invention will now be described with reference to an embodiment.

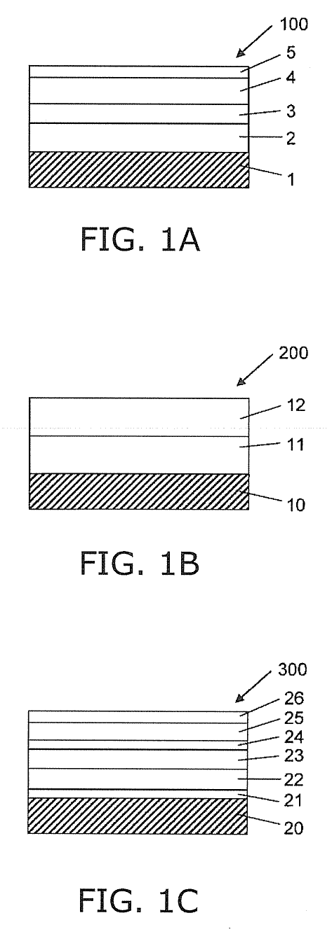

The embodiment is described with reference to FIGS. 1 to 3.

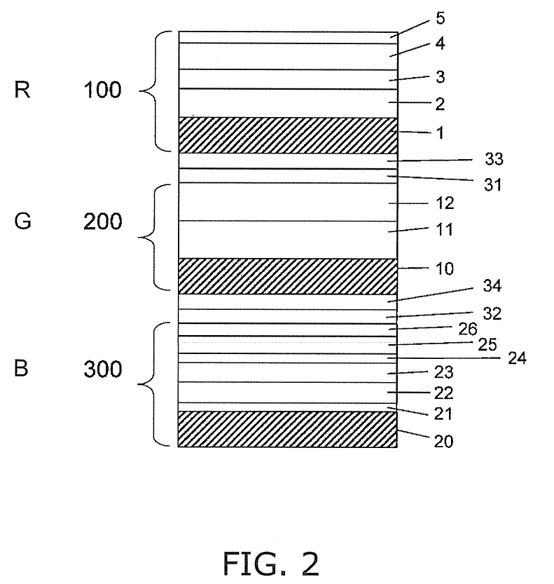

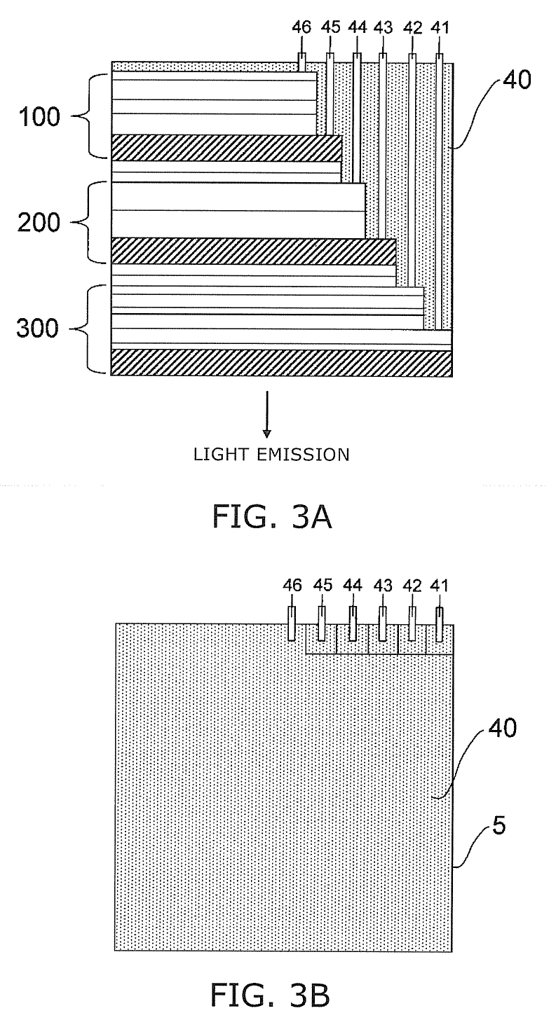

FIG. 1A is a cross-sectional view of a red LED element emitting red light, FIG. 1B is a cross-sectional view of a green LED element emitting green light, FIG. 1C is a cross-sectional view of a blue LED element emitting blue light, FIG. 2 is a schematic cross-sectional view of a stacked body in which the blue LED element, the green LED element, and the red LED element are stacked, FIG. 3A is a schematic cross-sectional view of a visible LED device comprising the stacked body of FIG. 2, and FIG. 3B is a schematic plan view of the visible LED device of FIG. 3A.

FIG. 1A is a cross-sectional schematic view showing the structure of the red LED element constituting the visible LED device.

In this embodiment, LED elements emitting the three primary colors of red, green, and blue are grown on respective substrates and bonded together with an optical filter interposed between the LEDs. With electrodes formed thereon, the LED elements for the three primary colors are formed into one chip. In this figure, the light emitting direction of the visible LED device is downward.

The red LED element 100 comprises a p-AlGaAs lower cladding layer 2, a p-AlGaAs active layer 3, an n-AlGaAs upper cladding layer 4, and an n-AlGaAs contact layer 5 formed on a p-GaAs substrate 1. The semiconductor layers formed on the p-GaAs substrate 1 are sequentially formed by MOCVD (metal organic chemical vapor deposition), for example. The red LED element 100 emits a light having a spectrum peak at a wavelength range of red.

The green LED element 200 comprises a p-GaP layer 11 and an n-GaP layer 12 formed on a p-GaP substrate 10. The semiconductor layers formed on the p-GaP substrate 10 are sequentially formed by LPE (liquid phase epitaxy), for example. The green LED element 200 emits a light having a spectrum peak at a wavelength range of green.

The blue LED element 300 comprises a GaN buffer layer 21, an n-GaN contact layer 22, an n-AlGaN lower cladding layer 23, a p-InGaN active layer 24, a p-AlGaN upper cladding layer 25, and a p-GaN contact layer 26 formed on a sapphire substrate 20. The semiconductor layers formed on the sapphire substrate 20 are sequentially formed by MOCVD, for example. The blue LED element 300 emits a light having a spectrum peak at a wavelength range of blue.

FIG. 2 shows the situation where these LED elements are stacked. The stacked LED elements constitute one element of the visible LED device of this embodiment. The blue LED element, the green LED element, and the red LED element are stacked with the substrates 20, 10, and 1 facing down to constitute one LED element of the visible LED device of this embodiment.

Further, an optical filter 31 is provided between the red LED element 100 and the green LED element 200. At least one of absorbance and reflectance of the optical filter 31 is higher at the wavelength range of green than at the wavelength range of red. The optical filter 31 may be a band-pass filter which allows a light of the wavelength range of red which is included in the light emitted from the red LED element 100 to pass through. Alternatively, the optical filter 31 may be a high-cut filter which reflects or absorbs lights having wavelengths shorter than that of a light of the wavelength range of red which is included in the light emitted from the red LED element 100.

An optical filter 32 is also provided between the green LED element 200 and the blue LED element 300. At least one of absorbance and reflectance of the optical filter 32 is higher at the wavelength range of blue than at the wavelength range of blue. The optical filter 32 may be a band-pass filter which allows a light of the wavelength range of green which is included in the light emitted from the green LED element 200 and a light of the wavelength range of red which is included in the light emitted from the red LED element 100 to pass through. Alternatively, the optical filter 32 may be a high-cut filter which reflects or absorbs lights having wavelengths shorter than that of a light of the wavelength range of green which is included in the light emitted from the green LED element 200.

Next, a process for forming this LED element is described.

As shown in FIG. 2, as the optical filter 31, a dichroic filter which blocks light at green and shorter wavelengths is formed by vapor deposition on the n-GaP layer 12 of the green LED element 200, for example. Furthermore, as the optical filter 32, a dichroic filter which blocks light at blue and shorter wavelengths is formed by vapor deposition on the p-GaN layer 26 of the blue LED element 300, for example.

A translucent resin 33 such as an epoxy resin adhesive is applied onto the green LED element 200 provided with the dichroic filter 31, and the substrate 1 constituting the red LED element 100 is bonded onto the green LED element 200. A translucent resin 34 such as an epoxy resin adhesive is applied onto the blue LED element 300 provided with the dichroic filter 32, and the substrate 10 constituting the green LED element 200 is bonded onto the blue LED element 300. That is, in this structure, the green LED element is adjacent to the blue LED element, and the red LED element is adjacent to the green LED element.

Next, the stacked body including the LED elements and optical filters shown in FIG. 2 is used to form a visible LED device.

As shown in FIG. 3B, by using a photoresist, a corner of the upper surface of the stacked body including the LED elements is dry etched to partly expose the n-GaN contact layer 22 and the p-GaN contact layer 26 of the blue LED element, the p-GaP substrate 10 and the n-GaP layer 12 of the green LED element, and the p-GaAs substrate 1 of the red LED element. Electrodes are formed later on each of the exposed portions and the n-AlGaAs contact layer 5 at the upper surface.

Next, an insulating film 40 is formed on the surface of the etched LED element. The insulating film 40 is illustratively made of silicon oxide.

Next, the above-mentioned electrodes are formed. To form the electrodes, the insulating film 40 is trench etched so that trenches reaching the n-GaN contact layer 22, the p-GaN contact layer 26, the p-GaP substrate 10, the n-GaP layer 12, the p-GaAs substrate 1, and the n-AlGaAs contact layer 5 are formed on the respective layers. Then the trenches are filled with copper, for example, to form electrodes 41-46 in the trenches and on the surface of the insulating film 40. The electrode 41 is connected to the n-GaN contact layer 22, the electrode 42 is connected to the p-GaN contact layer 26, the electrode 43 is connected to the p-GaP substrate 10, the electrode 44 is connected to the n-GaP layer 12, the electrode 45 is connected to the p-GaAs substrate 1, and the electrode 46 is connected to the n-AlGaAs contact layer 5 (FIG. 3A).

Consequently, the basic structure of the visible LED device is formed.

The visible LED device emits blue light upon application of voltage between the electrodes 41 and 42, emits green light upon application of voltage between the electrodes 43 and 44, and emits red light upon application of voltage between the electrodes 45 and 46. The light emitting direction is the stacked direction of the LED elements 100, 200, and 300, which is the direction of the arrow in the figure. One of the blue light, the green light, and the red light is emitted by appropriately applying a voltage between the electrodes. A mixed color light including two of the blue light, the green light and the red light can also be emitted. Further, the voltages between the electrodes can be adjusted to mix the red light, green light, and blue light into mixed color light including desired visible light to be emitted. For example, a white light having a desired spectrum can be obtained. When the mixed color light is emitted, the wavelength and the spectrum thereof can be adjusted by appropriately adjusting the current flown through the LED elements 100, 200, and 300, respectively.

The dichroic filter can be formed by laminating thin films. The film material can be oxides, fluorides, sulfides, or metals. The dichroic filter has a characteristic of transmitting a particular wavelength band of visible light and reflecting the other wavelength bands. The transmitted and reflected wavelengths can be varied by changing the type of film materials and the manner of stacking.

In this embodiment, a dichroic filter is used as an optical filter. However, a color filter may be used instead. The dichroic filter is made of a multilayer dielectric film, having the characteristic of transmitting and reflecting particular wavelengths.

As a major method to form a color filter, pigment having a particle diameter of approximately 0.1 μm is dispersed using a dispersant. The type of pigment can be monoazo-based or triphenylmethane-based, and can be suitably selected to vary the transmitted wavelength.

The color filter is illustratively based on a resist, having the characteristic of transmitting a particular range of wavelengths. Furthermore, the color filter can be used as an adhesive between the LED elements, thereby eliminating the need to use an extra adhesive.

While the filter 32 between the blue LED element and the green LED element is a filter blocking light at blue and shorter wavelengths in the above embodiment, a filter blocking only blue light may also be used. Likewise, while the filter 31 between the green LED element and the red LED element is a filter blocking light at green and shorter wavelengths in the above embodiment, a filter blocking only green light may also be used.

In the above embodiment, the optical filter has the characteristic of blocking the shorter wavelength light of the adjacent LED elements. However, the filter may include the characteristic of reflecting such light.

In the above embodiment, the filter between the blue LED element and the green LED element is formed on the blue LED element and then bonded to the green LED element. However, this filter may be formed on the green LED element using an adhesive. The same also applies to the filter between the green light emitting layer and the red light emitting layer.

Furthermore, in the emission of white light and other multicolor light, the three primary colors are not limited to red, green, and blue. In such a case (in the case of three primary colors other than the set of red, green, and blue), the characteristic of the optical filter can be selected so as to block the shorter wavelength light of the lights from the adjacent LED elements.

Moreover, a filter reflecting red light may be disposed on the n-AlGaAs contact layer 5 of the red LED element 100 to increase the light emission efficiency.

Thus, in the visible LED device including stacked LED elements according to this embodiment, light with a shorter wavelength is prevented from being incident on the LED element with a longer wavelength, and light of a desired color can be emitted with a desired intensity.

1. A visible light emitting device comprising:
three types of LED elements stacked one on another, each of the LED elements having a light emitting layer configured to emit light of one of three primary colors; and
first and second optical filters, each of the first and second optical filters disposed between two adjacent ones of the LED elements, and each of the first and second optical filters being operable to reflect or absorb a shorter wavelength light of the lights emitted from two adjacent LED elements.

2. The visible light emitting device according to claim 1, wherein the first and second optical filters have a characteristic of reflecting the light.

3. The visible light emitting device according to claim 1, wherein mixed color light is taken out, the mixed color light including each light emitted from the three types of LED elements.

4. The visible light emitting device according to claim 1, wherein the three types of LED elements are stacked sequentially in an order from the LED element of a longer emission wavelength, and the light is taken out in a stacked direction.

5. The visible light emitting device according to claim 1,
wherein
the light emitted from a first LED element of the three types of LED elements which has longest wavelength is taken out through others of the three types of LED elements and through the first and second optical filters,
the light emitted from a second LED element of the three types of LED elements which has second longest wavelength is taken out through a third LED element of the three types of LED elements which has shortest wavelength and through one of the first and second optical filters, and
the light emitted from the third LED element is taken out without passing the first and second LED elements and the first and the second optical filters.

6. The visible light emitting device according to claim 1, wherein each of the three types of LED elements has electrical connections extending in the stacked direction.

7. The visible light emitting device according to claim 1, wherein the each of the three types of LED elements has electrodes which are extending to a surface opposite to a surface from which the light is taken out.

8. The visible light emitting device according to claim 1, wherein voltage can be separately applied to each of the three types of LED elements.

9. A visible light emitting device comprising a stacked body including:
a first light emitting element which emits a light having a spectrum peak at a first wavelength range;
a second light emitting element which emits a light having a spectrum peak at a second wavelength range which is shorter than the first wavelength range; and
an optical filter provided between the first and second light emitting elements, at least one of absorbance and reflectance of the optical filter being higher at the second wavelength range than at the first wavelength range.

10. A visible light emitting device comprising a stacked body including:
a first light emitting element which emits a light having a spectrum peak at a first wavelength range;
a third light emitting element which emits a light having a spectrum peak at a third wavelength range which is different from the first wavelength range;
a second light emitting element provided between the first and third light emitting elements, the second light emitting element emitting a light having a spectrum peak at a second wavelength range which is different from the first and third wavelength ranges;
a first optical filter provided between the first and second light emitting elements, at least one of absorbance and reflectance of the first optical filter being higher at the second wavelength range than at the first wavelength range; and
a second optical filter provided between the second and third light emitting elements, at least one of absorbance and reflectance of the second optical filter being higher at the third wavelength range than at the second wavelength range.

11. The visible light emitting device according to claim 10, wherein
the first wavelength range is longer than the second wavelength range, and
the second wavelength range is longer than the third wavelength range.

12. The visible light emitting device according to claim 10, wherein the first, the second and the third wavelength range correspond to three primary colors.

13. The visible light emitting device according to claim 9, wherein mixed color light is taken out, the mixed color light including each light emitted from the first, the second and the third light emitting elements.

14. The visible light emitting device according to claim 13, wherein mixed color light includes a white light.

15. The visible light emitting device according to claim 9,
wherein
the light emitted from the first light emitting element is taken out through the second and the third light emitting elements and through the first and second optical filters,
the light emitted from the second light emitting element is taken out through the third light emitting element and through the second optical filter, and
the light emitted from the third light emitting element is taken out without passing the first and the second light emitting elements and the first and the second optical filters.

16. The visible light emitting device according to claim 9, wherein each of the first, the second and the third light emitting elements has electrical connections extending in a stacked direction.

17. The visible light emitting device according to claim 9, wherein the each of t the first, the second and the third light emitting elements has electrodes which are extending to a surface opposite to a surface from which the light is taken out.

18. The visible light emitting device according to claim 9, wherein voltage can be separately applied to each of the first, the second and the third light emitting elements.

19. The visible light emitting device according to claim 9, wherein the first and the second optical filters are dichroic filters.

20. The visible light emitting device according to claim 9, wherein the first and the second optical filters are color filters.
